(19) United States
(12) Patent Application Publication
(10) Pub. No.: US 2026/0097697 A1
(43) Pub. Date: Apr. 9, 2026

(54) SEAT ARRANGEMENT AND VEHICLE

(71) Applicants: Volkswagen Aktiengesellschaft, Wolfsburg (DE); AUDI AG, Ingolstadt (DE)

(72) Inventors: Kevin TORNER, Wolfsburg (DE); Hannah KUEHN, Koesching (DE)

(73) Assignees: Volkswagen Aktiengesellschaft, Wolfsburg (DE); AUDI AG, Ingolstadt (DE)

(21) Appl. No.: 19/353,162

(22) Filed: Oct. 8, 2025

(30) Foreign Application Priority Data
Oct. 9, 2024 (DE) 10 2024 129 155.9

(51) Int. Cl. B60N 2/90; B60K 1/04; B60N 2/005; B60R 16/023; B60R 16/033; B60R 16/04; H05K 7/20

(52) U.S. Cl. CPC B60N 2/90; B60K 1/04; B60N 2/005; B60R 16/023; B60R 16/033; B60R 16/04; H05K 7/20863; B60K 2001/0433

(57) ABSTRACT

The invention relates to a seat arrangement for a vehicle, comprising a seat base made of a plastic material, an electrical and/or electronic component arranged within the seat base that functions as a heat source, and an electrochemical energy storage arranged within the seat base that is heat-sensitive, wherein the seat base thermally separates the electrical and/or electronic component from the electrochemical energy storage.

This nonprovisional application claims priority under 35 U.S.C. § 119 (a) to German Patent Application No. 10 2024 129 155.9, which was filed in Germany on Oct. 9, 2024, and which is herein incorporated by reference.

### BACKGROUND OF THE INVENTION

### Field of the Invention

The present invention relates to a seat arrangement for a motor vehicle and a motor vehicle with such a seat arrangement.

### Description of the Background Art

Battery-electric vehicles (BEVs) are becoming increasingly widespread. Many battery-electric vehicles have a so-called “frunk”-a storage compartment positioned beneath the hood. Even internal-combustion-engine vehicles may have a frunk. This makes it necessary to reposition components, especially electrical and/or electronic components. For example, such components can be placed below a second seat row or rear seat row. However, some of these components may act as heat sources while others may be heat-sensitive. This necessitates thermal separation of the components.

DE 11 2008 003 874 B4, which corresponds to US 2011/0109133, discloses a vehicle seat arrangement comprising a seat cushion designed for mounting on a vehicle, wherein the seat cushion comprises a foam layer and a first foamed polymer layer positioned adjacent to the foam layer, wherein the first foamed polymer layer defines a first cavity configured to receive an electrical component.

GB 2574788 A shows a seat base for a seat row of a vehicle.

DE 10 2008 022 772 A1, which corresponds to US 2008/0296935, discloses a seat base with an airflow channel that allows a battery to be supplied with cooling air.

### SUMMARY OF THE INVENTION

It is therefore an object of the present invention to provide a seat arrangement for a motor vehicle in which thermal separation of components is possible.

An aspect of the invention concerns a seat arrangement for a motor vehicle. The seat arrangement includes a seat base made, for example, of a plastic material, an electrical and/or electronic component arranged within the seat base that acts as a heat source, and a heat-sensitive electrochemical energy storage arranged within the seat base, wherein the seat base thermally separates the electrical and/or electronic component from the electrochemical energy storage.

Through such a seat arrangement—in particular through such a seat base—it is possible to thermally separate the heat-generating electrical and/or electronic component from the heat-sensitive electrochemical energy storage so that no heat is transferred from the electrical and/or electronic component to the electrochemical energy storage.

The seat arrangement is suitable for both battery-electric vehicles and vehicles powered by a combustion-engine. It is particularly suitable for a rear seat row or a second seat row of the vehicle. The seat base can comprise a foamed plastic material. Any plastic material may be used, e.g. polypropylene, polystyrene or polyethylene. Preferably, the seat base is produced by foaming the plastic material in a mold. The mold defines the geometry of the seat base. For example, using the mold, recesses, breaches, mounting areas, channels or similar features can be formed in the seat base. Alternatively, the seat base can be formed from a plastic half-blank by a subtractive manufacturing process.

The seat base can comprise several mounting areas into which the electrical and/or electronic component and the electrochemical energy storage can be placed. However, the electrical and/or electronic component and the electrochemical energy storage are placed in different mounting areas of the seat base. The seat arrangement may contain any number of different electrical and/or electronic components. The following discussion refers only to one electrical and/or electronic component. The seat base may also contain any other components or parts of a vehicle powered by a combustion-engine.

The seat base can surround or encapsulates the electrical and/or electronic component and the electrochemical energy storage. This does not preclude the aforementioned mounting areas for the electrical and/or electronic component and/or the electrochemical energy storage from being open in one direction, so that the electrical and/or electronic component and the electrochemical energy storage can be inserted or introduced into the seat base. For example, the electrical and/or electronic component and the electrochemical energy storage are mounted on a vehicle chassis, while the seat base is fitted over them.

The plastic material can be expanded polypropylene (EPP). As mentioned above, other plastic materials may also be used.

The seat base can have a support structure, for example, a wire structure, that is permeable to radio waves. The support structure bears or supports the seat base. However, the radio waves from the electrical and/or electronic component—e.g. a communication module—are not or only minimally affected or shielded. This can be achieved, for example, by spacing the wires of the support structure at a suitable distance so that the support structure is continuous or permeable to radio waves. The seat base itself bears the seat row and supports its own weight or the weight of a seat cushion and passengers seated on the seat cushion. In particular, the seat base replaces a so-called seat pan that is made of metal parts. The seat base may also, for example, have embedded fasteners for attaching the seat base to the vehicle chassis.

The electrical and/or electronic component can comprise a main fuse box and/or a communication module. As mentioned above, any number of different electrical and/or electronic components may be provided. Because the seat base is made of plastic, it does not undesirably shield the communication module. The seat base does not shield radio waves because it is made of plastic.

The electrochemical energy storage is a low-voltage accumulator. For example, it is a 12-volt accumulator. The electrochemical energy storage may be a lithium accumulator.

The seat base can have a first mounting area for the electrical and/or electronic component and a second mounting area for the electrochemical energy storage, wherein the seat base has a wall section positioned between the first mounting area and the second mounting area to thermally separate the electrical and/or electronic component from the electrochemical energy storage. The seat base may have any number of such mounting areas. The wall section can be made of the same plastic material as the seat base. The mounting areas may be formed as recesses or cavities in the seat base. For example, the mounting areas can be produced by forming corresponding contours on a mold that is foamed with the plastic material. Alternatively, the mounting areas can be produced by a subtractive process, in particular a milling process, in the seat base or in a plastic half-blank.

The wall section can have a breach which a cable from the electrical and/or electronic component to the electrochemical energy storage passes. The breach can be a hole. It can also be a channel or a slot that is open in one direction. After passing the cable through the breach, it can be closed with a thermally insulating material.

The seat arrangement can have a fan for ventilating the first mounting area. The fan can, for example, provide fresh air to the first mounting area. Also, the fan can expel warm air from the first mounting area. The second mounting area may also have such a fan. Any number of fans may be provided.

The seat base can have a cable duct through which cables to the electrical and/or electronic component and wires from the electrical and/or electronic component pass. The cable duct can be a cutout that extends from the first mounting area to the surroundings of the seat base. Alternatively, the cable duct can be a perforation or a hole.

The seat arrangement can have a seat row, wherein the seat base supports the seat row. In particular, the seat base bears the weight of the seat row and, if applicable, of passengers seated on the seat row. The seat row is particularly a second seat row or rear seat row of the vehicle.

The seat arrangement can have a vehicle chassis, wherein the seat row is attached to the vehicle chassis, and the seat base is positioned between the seat row and the vehicle chassis. To attach the seat row to the vehicle chassis, suitable attachment points or mounting points may be provided on the vehicle chassis. In particular, the seat row's seat belts are directly mounted to the vehicle chassis.

The seat base can be connected to the vehicle chassis. For example, clamps or clip elements can be used. A threaded connection is also possible. The plastic material of the seat base may contain embedded fasteners for attaching the seat base to the vehicle chassis.

The electrical and/or electronic component and/or the electrochemical energy storage can be connected to the vehicle chassis. Preferably, the electrical and/or electronic component and/or the electrochemical energy storage are not rigidly fixed to the seat base. The seat base can be fitted over the electrical and/or electronic component and/or the electrochemical energy storage that are mounted on the vehicle chassis.

The seat arrangement can have a high-voltage energy storage mounted on the vehicle chassis, and the seat base can be positioned above the high-voltage energy storage. In particular, the electrical and/or electronic component and/or the electrochemical energy storage can be placed between the high-voltage energy storage and the seat base.

Another aspect of the invention concerns a motor vehicle with such a seat arrangement.

The motor vehicle can be a battery-electric vehicle (BEV) or a hybrid vehicle. The motor vehicle can be, for example, a passenger car.

The invention also includes further developments of the motor vehicle described in accordance with the invention, which possess the features already described in the context of further developments of the seat arrangement according to the invention. Therefore, the corresponding further developments of the motor vehicle are not described again here.

The invention also comprises combinations of the features of the described examples.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic side view of an example of a motor vehicle;

FIG. 2 shows a schematic top view of a seat base for the motor vehicle according to FIG. 1; and

FIG. 3 shows a schematic side view of a seat arrangement for the motor vehicle according to FIG. 1.

### DETAILED DESCRIPTION

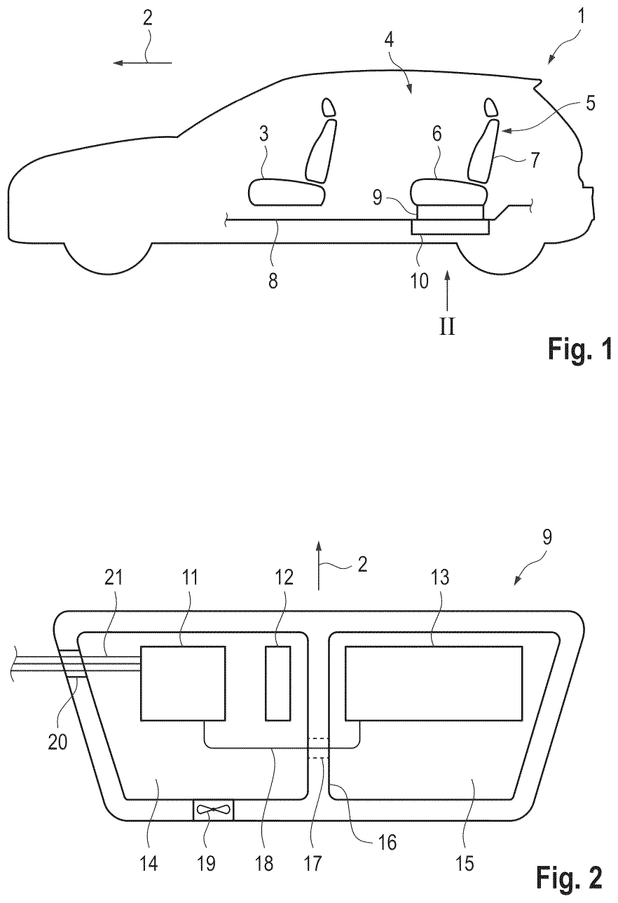

FIG. 1 shows a motor vehicle 1. The motor vehicle 1 may, for example, be a passenger car. The motor vehicle 1 is a battery-electric vehicle (BEV) or a hybrid vehicle. It may also be an internal-combustion-engine vehicle. The motor vehicle 1 moves in a direction 2. The motor vehicle 1 has a driver seat 3 and a not shown passenger seat.

Furthermore, the motor vehicle 1 has a seat arrangement 4. The seat arrangement 4 has a seat row 5 positioned behind the driver seat 3. For example, three passengers can sit on seat row 5. Seat row 5 is a second seat row or rear seat row of the motor vehicle 1. Seat row 5 has a single-piece or multi-piece seat cushion 6 and a single-piece or multi-piece backrest 7. In addition to seat row 5, the seat arrangement 4 includes a vehicle chassis 8, which is only very schematically shown in FIG. 1.

The seat arrangement 4 further includes a seat base 9 positioned between the vehicle chassis 8 and seat row 5, in particular between seat row 5 and its seat cushion 6, and the seat base 9 supports seat row 5. The seat base 9 is made of a plastic material. The plastic material is foamed or expanded. For example, expanded polypropylene (EPP) may be used. However, any other plastic material may also be used.

The seat base 9 is connected to the vehicle chassis 8. For example, suitable snap-or-clamp connections may be provided. A threaded connection between seat base 9 and vehicle chassis 8 is also possible. The seat base 9 may have fastening elements embedded in the plastic material.

The seat base 9 bears the weight of seat cushion 6 and the weight of passengers seated on seat cushion 6. Both the seat row 5 itself and the seat row 5's seat belts are directly attached to the vehicle chassis 8, so that, for example, forces acting on the seat belts during braking of the motor vehicle 1 are transmitted to the vehicle chassis 8 rather than to seat base 9. Attachment points or fastening points are provided to fasten seat row 5 and its seat belts to vehicle chassis 8.

The seat base 9 may have a support structure, in particular a wire support structure or a wire frame. The support structure may be made of a metallic material. The support structure is, however, designed such that it does not or only minimally affect radio waves. For example, the wires of the support structure can be positioned at a suitable distance from each other. In addition, fastening elements for attaching seat base 9 to vehicle chassis 8 may also be embedded in the plastic material.

Further on the vehicle chassis 8 a high-voltage energy storage 10 is mounted. Said high-voltage energy storage 10 is arranged under the seat base 9 in orientation of FIG. 1. Therefore seat basis 9 is arranged between seat row 5 and high-voltage energy storage 10.

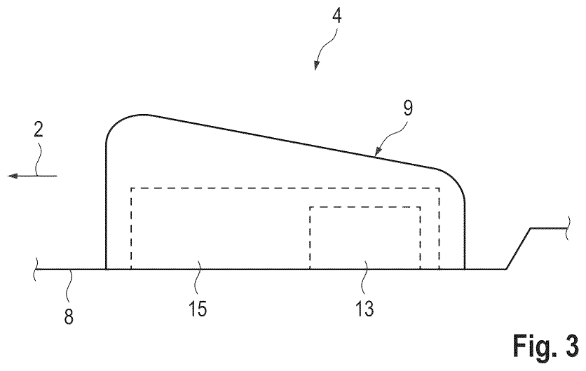

FIG. 2 shows a top view of seat base 9. The seat base 9 is shown in the top view, from which the side view orientation of the seat base can be derived. FIG. 3 shows a side view of an example of a seat arrangement 4 of the motor vehicle 1 of FIG. 1. The following refers to FIGS. 2 and 3 simultaneously.

As shown in FIG. 3, the seat base 9 is wedge-shaped when viewed from the side. In addition to the vehicle chassis 8 and the seat base 9, the seat arrangement 4 has at least one electrical and/or electronic component 11, 12 arranged inside the seat base 9. Any number of electrical and/or electronic components 11, 12 may be provided. In the present case, for example, a first electrical and/or electronic component 11 in the form of a main fuse box and a second electrical and/or electronic component 12 in the form of a communication module are provided. The fact that the seat base 9 is made of a plastic material means that the seat base 9 does not shield the second electrical and/or electronic component 12 in the form of a communication module in an undesirable manner. In particular, the seat base 9 does not shield radio waves. This can also be achieved by designing the aforementioned support structure in such a way that it does not shield radio waves. In the event that the motor vehicle 1 is a combustion engine-powered motor vehicle, any other components of the motor vehicle 1 may be installed in the seat base 9.

In addition to the first electrical and/or electronic component 11 and/or the second electrical and/or electronic component 12, the seat arrangement 4 has an electrochemical energy storage 13 positioned within seat base 9. The electrochemical energy storage 13 is preferably a low-voltage accumulator. Both electrical and/or electronic components 11, 12 and the electrochemical energy storage 13 are fully positioned within seat base 9.

Electrical and/or electronic components 11, 12 act as heat sources and thus emit heat, while electrochemical energy storage 13 is heat-sensitive. Using seat base 9, the electrical and/or electronic components 11, 12 and electrochemical energy storage 13 can be thermally separated such that the electrical and/or electronic components 11, 12 do not or only partially transfer heat to electrochemical energy storage 13.

In particular, seat base 9 has a first mounting area 14 open downward (orientation of FIG. 1) for the electrical and/or electronic components 11, 12. The first mounting area 14, for example, is a recess or cavity in seat base 9. Seat base 9 further has a second mounting area 15 for electrochemical energy storage 13. The second mounting area 15 is also a recess or cavity in seat base 9.

Between first mounting area 14 and second mounting area 15 there is a wall section 16 made of the same plastic material as seat base 9. The wall section 16 is part of seat base 9 and thermally separates first mounting area 14 from second mounting area 15. This allows the electrical and/or electronic components 11, 12 and electrochemical energy storage 13 to be thermally separated.

To enable an electrical connection between electrical and/or electronic components 11, 12 and electrochemical energy storage 13, the wall section 16 can have a breach 17 through which a conductor from the electrical and/or electronic components 11, 12 to electrochemical energy storage 13 passes. The breach 17 can be a hole or a slot that is open in one direction. After the conductor passes through breach 17, it can be closed with a thermally insulating material.

Electrical and/or electronic components 11, 12 and/or the electrochemical energy storage 13 preferably are rigidly connected to the vehicle chassis 8 and not rigidly fixed to seat base 9. Alternatively, however, it is also possible for the electrical and/or electronic components 11, 12 and/or the electrochemical energy storage 13 to be connected to the seat base 9.

The first mounting area 14 may have a fan 19 for ventilating the first mounting area 14. The fan can, for example, supply fresh air to the first mounting area 14. Alternatively, heated air can be extracted from the first mounting area 14 with the aid of fan 19. Fan 19 is optional. The fan 19 is optional. The second mounting area 15 may also have such a fan.

Seat base 9 further has a cable duct 20 that extends from the first mounting area 14 to the surroundings of seat base 9. Cables 21 leading to the electrical and/or electronic components 11, 12 and/or cables 21 coming from the electrical and/or electronic components 11, 12 can be routed through cable duct 20. The second mounting area 15 can also have a cable duct 20.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A seat arrangement for a vehicle, the seat arrangement comprising:
a seat base made of a plastic material;
an electrical and/or electronic component arranged within the seat base that functions as a heat source; and
an electrochemical energy storage arranged within the seat base that is heat-sensitive,
wherein the seat base thermally separates the electrical and/or electronic component from the electrochemical energy storage.

2. The seat arrangement according to claim 1, wherein the plastic material is expanded polypropylene.

3. The seat arrangement according to claim 1, wherein the seat base has a support structure or a wire structure that is permeable to radio waves.

4. The seat arrangement according to claim 1, wherein the electrical and/or electronic component comprises a main fuse box and/or a communication module.

5. The seat arrangement according to claim 1, wherein the electrochemical energy storage is a low-voltage accumulator.

6. The seat arrangement according to claim 1, wherein the seat base has a first receptacle for receiving the electrical and/or electronic component and a second receptacle for receiving the electrochemical energy storage, and wherein the seat base has a wall section positioned between the first receptacle and second receptacle to thermally separate the electrical and/or electronic component from the electrochemical energy storage.

7. The seat arrangement according to claim 6, wherein the wall section has a breach through which a wire from the electrical and/or electronic component to the electrochemical energy storage passes.

8. The seat arrangement according to claim 6, further comprising a fan for ventilating the first receptacle.

9. The seat arrangement according to claim 1, wherein the seat base has a cable duct through which cables to the electrical and/or electronic component and/or conductors from the electrical and/or electronic component pass.

10. The seat arrangement according to claim 1, further comprising a seat row, wherein the seat base bears the seat row.

11. The seat arrangement according to claim 10, further comprising a vehicle chassis, wherein the seat row is attached to the vehicle chassis and the seat base is positioned between the seat row and the vehicle chassis.

12. The seat arrangement according to claim 11, wherein the seat base is connected to the vehicle chassis.

13. The seat arrangement according to claim 11, wherein the electrical and/or electronic component and/or the electrochemical energy storage are connected to the vehicle chassis.

14. The seat arrangement according to claim 11, further comprising a high-voltage energy storage mounted on the vehicle chassis, wherein the seat base is positioned above the high-voltage energy storage.

15. A vehicle comprising the seat arrangement according to claim 1.

16. A seat base for a vehicle, the seat base comprising:
a first region formed such to contain a battery therein;
a second region formed such to contain at least one electrical component; and
a barrier that is integrally formed with the seat base, the barrier substantially thermally insulating the first region from the second region, the barrier separating the first region from the second region, the barrier and the seat base being made of a plastic material.

17. The seat base according to claim 16, wherein the seat base is permeable to radio waves.

18. The seat base according to claim 16, wherein an upper surface of the seat base is adapted to support a foam cushion for a passenger seat of a motor vehicle.
